(19) United States
(12) Patent Application Publication
(10) Pub. No.: US 2015/0355538 A1
(43) Pub. Date: Dec. 10, 2015

(54) FABRICATION OF BINARY MASKS WITH ISOLATED FEATURES

(71) Applicant: INDIAN INSTITUTE OF TECHNOLOGY KANPUR, Uttar Pradesh (IN)

(72) Inventors: Govind Dayal SINGH, Kanpur, Uttar Pradesh (IN); Ramakrishna SUBRAMANIAM ANANTHA, Kanpur, Uttar Pradesh (IN); Janakarajan RAMKUMAR, Kanpur, Uttar Pradesh (IN)

(73) Assignee: Indian Institute of Technology Kanpur, Uttar Pradesh (IN)

(21) Appl. No.: 14/760,394

(22) PCT Filed: Dec. 11, 2013
(86) PCT No.: PCT/IB2013/060790

§ 371 Date: Jul. 10, 2015

(30) Foreign Application Priority Data
Jan. 10, 2013 (IN) 79/DEL/2013

(51) Int. Cl. G03F 1/80; C23F 1/00

(52) U.S. Cl. CPC G03F 1/80; C23F 1/00

(57) ABSTRACT

An environmentally benign method for producing binary microfabrication masks is disclosed. An optical target may be provided that includes a water-soluble polymer material in contact with an ultraviolet radiation transmittable substrate. A laser may be focused on a primary mask to produce a mask image, the mask image thereafter being reduced by demagnification optics to provide a reduced image. The optical target may be exposed to the reduced image to create features of reduced size from the primary mask. The water-soluble polymer exposed to the ultraviolet radiation may be ablated from the optical target. The optical target may be subsequently metalized using a metal vapor to coat the remaining polymer material and exposed substrate. The metalized optical target may be contacted with an aqueous fluid to remove the metalized polymer material leaving the binary mask.

### CROSS-REFERENCE TO RELATED APPLICATIONS

This application is a PCT application that claims the benefit of Indian Patent Application No. 79/DEL/2013, filed on Jan. 10, 2013, the entire contents of which are incorporated herein by reference in its entirety.

### BACKGROUND

Laser microfabrication masks with micron sized spatial features are used in a number of industrial processes including the fabrication of integrated circuits, MEMS devices, and materials with attractive optical properties. Such microfabrication masks may be fabricated by a number of processes to create masks with either continuous or isolated features. Masks having continuous features may be manufactured using photolithographic methods employing negative primary masks or by direct photo-writing on a substrate. Masks having isolated features, however, may typically be manufactured using photolithographic methods employing positive primary masks. Photolithography processes using positive primary masks are typically considered wet process techniques

Wet processing techniques typically use a polymer material fixed to a substrate material, thereby creating an optical target. The optical target may be exposed to an image created by a UV light source, such as a UV laser or other ionizing radiation sources (including, without limitation, e-beam or ion beam), directed through a primary mask. In a negative primary mask process, the polymer material may be chemically altered by exposure to the radiation to make it resistant to a subsequent developing (removal) step. In a positive primary mask process, the polymer material may be either ablated directly or chemically altered by exposure to the radiation to make it more susceptible to removal during a subsequent developing step. Isolated target features can be more readily fabricated using a positive primary mask process. Wet processing derives its name from the use of chemical washes used during the process, such as during substrate preparation, optical target developing, material removal/etching, and additional cleaning steps.

One potential drawback in wet fabrication processes is the type of chemicals that may be used both for a development stage and/or a final cleaning stage of the target. Typical polymer materials may use chemical solvents requiring special handling to prevent environmental contamination. It is therefore desirable to develop a wet process for fabricating binary masks having isolated features that may employ environmentally benign chemicals.

### SUMMARY

In an embodiment, a method of fabricating a laser binary microfabrication mask includes providing a radiation transmittable substrate, contacting the substrate with a water-soluble polymer material, thereby forming an optical target, exposing at least a portion of the optical target to a mask image formed by passing radiation through a primary mask, thereby etching at least a portion of the water-soluble polymer material, contacting the optical target with a metal vapor, thereby forming a metalized target comprising at least one metalized substrate portion and at least one metalized polymer material portion, and exposing the metalized target to an aqueous fluid, thereby removing the metalized polymer material portion.

In an embodiment, a system for fabricating a laser binary microfabrication mask may include a laser radiation source; a metal vapor source; a primary mask having a first side and a second side, the primary mask configured to receive radiation from the laser radiation source on the first side and to emit the radiation on the second side to form a mask image; and an optical target holder configured to hold an optical target, the optical target comprising a radiation transmittable substrate and a water-soluble polymer material, wherein the optical target holder is configured to perform one or more of the following: expose at least a portion of the optical target to the mask image to etch at least a portion of the water-soluble polymer material; contact the optical target with metal vapor from the metal vapor source to form a metalized target comprising at least one metalized substrate portion and at least one metalized polymer material portion; and expose the metalized target to an aqueous fluid to remove the metalized polymer material portion.

### BRIEF DESCRIPTION OF THE DRAWINGS

FIG. 1 illustrates a system for fabricating a binary laser microfabrication mask in accordance with the present disclosure.

FIGS. 2A-D illustrate one embodiment of a method to fabricate a binary laser microfabrication mask in accordance with the present disclosure.

FIG. 3 is a flow chart illustrating an embodiment of a method of producing a binary laser microfabrication mask in accordance with the present disclosure.

### DETAILED DESCRIPTION

Microfabrication techniques may find use in the production of many devices having micron and submicron features, such as integrated circuits, MEMS devices, and optical devices with unusual properties, such as photonic devices. Microfabrication methods may include both wet and dry processes. In wet processes, such as photolithography, a laser light beam may be focused on a primary mask to produce a mask image overlaid on an optical target coated with a polymer material. In photolithography, after exposure to the image, the polymer material may be solubilized to leave a blocking layer on the target which may thereafter be subjected to a succession of further steps, including, as one non-limiting example, exposure to a metal vapor to coat the target with a thin metal film.

One disadvantage of some forms of wet processes may include the use of a polymer material that can only be removed from the optical target through the use of environmentally intrusive solvents. Examples of such solvents may include one or more of acetone, methanol, isopropanol, ethyl glycol acetate, cyclopentanone, dimethyl formamide, and dimethyl sulfoxide, among others. After use, such solvents may require appropriate storage techniques to keep them away from the environment. It may therefore be appreciated that a photolithography process that may use a polymer material removable by simple aqueous solutions may improve the potential ecological impact of micromachining binary masks.

It may be appreciated that a binary mask produced by the method and system disclosed below may be used for a variety of microfabrication techniques, including but not limited to photolithography, direct laser writing, e-beam lithography, and ion beam lithography. While the reflectivity and resistance to thermal degradation of such binary masks may preferentially suggest their use with direct laser microfabrication techniques, it may be appreciated that techniques requiring lower laser power may similarly benefit from the use of such binary masks.

In an embodiment, a system for fabricating a laser binary microfabrication mask may include a laser radiation source; a metal vapor source; a primary mask having a first side and a second side, the primary mask configured to receive radiation from the laser radiation source on the first side and to emit the radiation on the second side to form a mask image; and an optical target holder configured to hold an optical target, the optical target comprising a radiation transmittable substrate and a water-soluble polymer material. The optical target holder can be configured to perform one or more of the following: expose at least a portion of the optical target to the mask image to etch at least a portion of the water-soluble polymer material; contact the optical target with metal vapor from the metal vapor source to form a metalized target comprising at least one metalized substrate portion and at least one metalized polymer material portion; and expose the metalized target to an aqueous fluid to remove the metalized polymer material portion. The radiation transmittable substrate can for example be a UV radiation transmittable substrate. The primary mask can for example be a primary microfabrication mask.

In one embodiment, the system may further include a demagnification optics system having a focal length to receive the mask image and to emit a demagnified mask image, wherein the optical target holder is further configured to expose at least a portion of the optical target to the demagnified mask image.

In one embodiment, the system may further include at least one of an attenuator and a homogenizer, each configured to be optically coupled to radiation from the laser radiation source. In another embodiment, the system may further include at least one of a cylindrical lens, a spherical lens, a doublet lens, a triplet lens, a synthetic fused silica lens, and a lens with an anti-reflective coating, for focusing radiation from the laser radiation source on the first side of the primary mask.

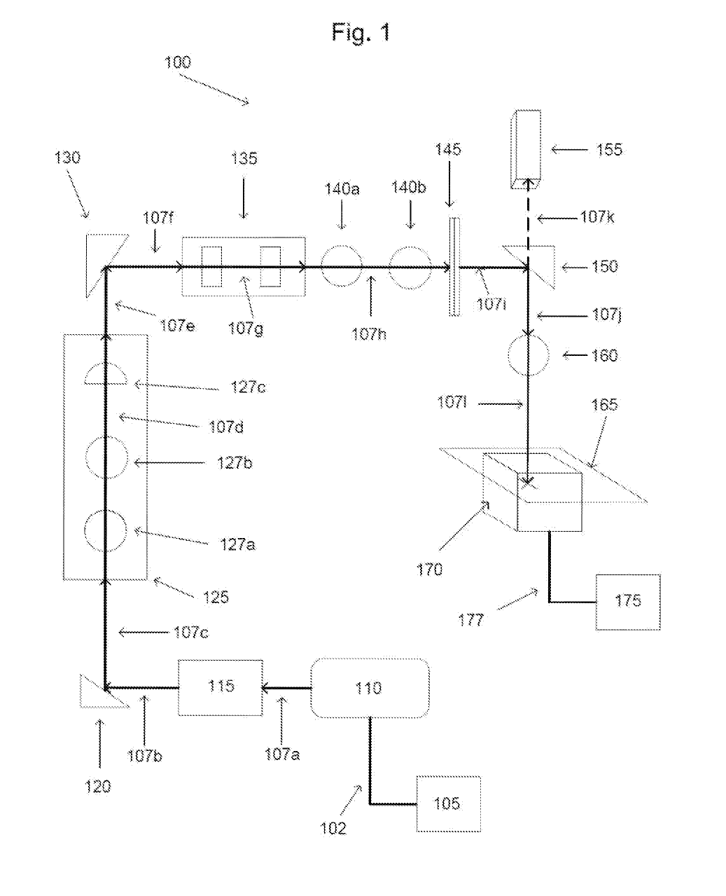

FIG. 1 illustrates one embodiment of a binary mask microfabrication system 100 having a laser 110, a variety of optical elements, such as 115-140a,b, in the beam path between the laser 110 and the primary microfabrication mask 145, and demagnification optics 160 located between the primary mask 145, and an optical target 165. The optical target 165 may be mounted on a movable stage 170, either directly or incorporated in a frame for stabilization. Both laser 110 and movable stage 170 may be controlled by computerized devices, such as a laser radiation output controller 105 to control the output radiation of the laser 110 and a computer 175 to control actuators associated with the movable stage 170. In one embodiment, the functions associated with controllers 105 and 170 may be performed by a single control device. In an alternative embodiment, controllers 105 and 170 may be performed by separate devices. The separate devices may be stand-alone, or may be in mutual electronic communication.

Laser 110 may include any laser used for microfabrication processes. Non-limiting examples of such lasers include a variety of excimer lasers, such as ArF, KrF, XeBr, XeCl, XeF, KrCl, and F₂, as well as non-excimer Nd:YAG, N₂ gas, and HeCd lasers. In some embodiments, the laser can be an ultraviolet (UV) laser. Depending on the laser used, the laser radiation output may lie within a radiation band of about 150 nm to about 1200 nm inclusive of endpoints. In some embodiments, the laser radiation output may lie within a radiation band of about 190 nm to about 360 nm inclusive of endpoints. In some non-limiting examples, the laser radiation output may include at least one wavelength of about 356 nm, about 308 nm, about 266 nm, about 248 nm, about 193 nm, or ranges between any two of these values. Table 1 provides examples of radiation wavelengths associated with some lasers.

TABLE 1

| | Wavelength |
|---|---|
| Laser Type | (nm) |
| ArF | 193 |
| KrF | 248 |
| XeBr | 282 |
| XeCl | 308 |
| XeF | 351 |
| KrCl | 222 |
| F2 | 157 |
| Nd: YAG | 266 and 354 |
| (4^{th} and 3^{rd} harmonic) | |
| HeCd | 325 and 442 |
| N₂ gas | 337 |

Laser controller 105 may control a variety of laser output parameters via laser control lines 102. For example, the laser output may be pulsed, continuous, or a combination of pulsed and continuous beams. In a non-limiting example, the irradiance of the laser output in continuous mode may be less than or equal to about 10 W/cm². In another non-limiting example, the laser output in pulsed mode may have a pulse energy fluence less than or equal to about 25 mJ/cm². In one non-limiting embodiment, the laser pulses may have a pulse width of about 1 ps to about 1 μs. In another non-limiting embodiment, the laser pulses may have a pulse width of about 1 ps to about 100 ns. Non-limiting examples of laser pulse widths may include a pulse width of about 1 ps, about 5 ps, about 10 ps, about 50 ps, about 100 ps, about 500 ps, about 1 ns, about 5 ns, about 10 ns, about 50 ns, about 100 ns, or ranges between any two of these values. The pulse width may be fixed for the duration of a particular machining process or may be dynamically varied according to process parameters. For example, pulse shaping may be useful for clean exposure of the optical target to the features of the primary mask image depending on the target material (substrate material and/or polymer material) and feature size. In another embodiment, the pulse width may be fixed at a specific width, such as at about 20 ns. The pulse frequency may also be fixed or dynamically adjusted during machining. In one embodiment, the pulse frequencies may be about 1 Hz to about 50 Hz. Examples of pulse frequency may include, without limitation, about 1 Hz, about 5 Hz, about 10 Hz, about 20 Hz, about 30 Hz, about 40 Hz, about 50 Hz, and ranges between any two of these values. In another embodiment, the pulse frequency may be about 10 Hz. Pulse frequency may be chosen to optimize the exposure of the optical target based on the composition of the substrate material and/or the polymer material, laser power, and laser wavelength.

The laser radiation output can travel an optical path such as the one illustrated in FIG. 1 by beam path 107a-1. Beam path 107a is a path from the laser output to attenuator 115 which may be used to reduce the beam power as required by the materials composing optical target 165. The output of attenuator 115 may be further directed through a series of focusing optical elements 127a-c of focusing optics system 125, along beam path 107d. The focusing elements 127a-c may include any of a variety or combination of elements, including but not limited to cylindrical lenses, spherical lenses, doublet lenses, triplet lenses, synthetic fused silica lenses and lenses with optical coatings, such as anti-reflective coatings. In one example, the focusing optics may comprise a group of two cylindrical lenses and a spherical lens. In one embodiment, the laser light output from the focusing optics may then be directed through a homogenizer 135 along beam path 107g to provide a uniform intensity beam to illuminate one side of the primary microfabrication mask 145. In one embodiment illustrated in FIG. 1, the output beam from attenuator 115 may pass through additional optical elements such as right angle prisms 120 and 130 along beam paths 107b-c, and 107e-f. Such right angle prisms may be used to maintain the required optical path length within a reasonably sized footprint for a manufacturing facility. Additional optical elements also may include field lenses 140a,b coupled by beam path 107h.

The primary microfabrication mask 145 includes features that will be imaged on optical target 165. The primary microfabrication mask may be fabricated from any of a number of materials or combination of materials, including metal sheets, polymer films, or metalized polymer films. Non-limiting examples of metallic sheets include stainless steel, chromium, aluminum or copper, although other malleable metals may also be used. In one embodiment, the metal sheets may have a thickness of about 15 μm to about 1 mm. In another embodiment, the metal sheet thickness may be from about 100 μm to about 150 μm. The metal sheets may be composed of a single metal. Alternately, the metal sheets may comprise layered metals or metals with polymer or metallic coatings. Polymer films may include, without limitation, polyimide, polythene and polytetrafluoroethylene. The primary microfabrication mask may be fabricated by a number of methods. Some non-limiting methods for manufacturing the primary mask may include CNC milling, electrical discharge machining, electro-chemical machining, laser microfabrication, laser etching, electronic beam machining, ion beam machining and plasma beam machining. The primary microfabrication mask may also be fabricated by direct laser etching that uses demagnifying optics to create a binary mask with reduced features from another binary mask.

As disclosed above, the output radiation from laser 110 can be focused on the upstream side of the primary mask 145. On illumination, the features machined in the primary mask may produce an image projected from the downstream side of the primary mask. The image may then be projected through demagnification optics 160 onto optical target 165. In one embodiment, the image from primary mask 145 may pass directly to the demagnification optics. In another embodiment, the image may be directed along optical path 107i to a dichroic mirror/beam splitter 150. One image from the dichroic mirror may be directed along beam path 107k to a camera 155—comprising, for example, a CCD camera with a phosphor screen—to record and/or analyze the image. The camera 155 may be positioned at an angle with respect to the mirror in order to obtain a useful image. In one non-limiting embodiment, the image data output produced by the camera may be used to program the laser output controller. In an alternative embodiment, the CCD output image may be used to control the position of a movable stage (see below) on which the optical target 165 is affixed. A second image from dichroic mirror 150 may be directed along beam path 107j to the demagnification optics 160.

Demagnification optics 160 may comprise a number of optical elements. Some non-limiting examples include spherical lenses, Fresnel lenses, diffractive optics systems, doublet lenses, triplet lenses, synthetic fused silica lenses and coated lenses. Spherical lenses may further include corrections for spherical aberrations, coma and astigmatism. Lens coatings may include anti-reflective coatings among others. The demagnification optics may be used to project a reduced image of primary mask 145 onto the optical target 165 based on the focal length of the demagnification optics.

One metric to measure the amount of image reduction due to the demagnification optics is the demagnification ratio. The demagnification ratio is the ratio of the object distance divided by the image distance. The object distance is the optical distance from the primary microfabrication mask 145 to the demagnifying optics 160 (for example, a distance measured in FIG. 1 as the length of beam path 107i+beam path 107j). The image distance is the optical distance from the demagnifying optics 160 to the optical target 165 (for example, the distance of beam path 107l). A demagnification ratio greater than 1 indicates that the image on the target has smaller features than those on the primary micromachining mask. In a non-limiting example, the demagnification ratio may be about 2 to about 25. In another non-limiting example, the demagnification ratio may be about 2 to about 12. In another non-limiting example, the demagnification ratio may be about 10. Non-limiting examples of the demagnification ratio may include about 2, about 5, about 10, about 15, about 20, about 25, or ranges between any two of these values.

Although FIG. 1 illustrates an embodiment that incorporates a variety of optical elements configured in a specific order, it may be appreciated that other embodiments may include alternative and/or additional optical elements such as slits, collimators, and shutters. Further, alternative embodiments may lack certain of the optical elements illustrated in FIG. 1, or distribute the elements in a different order along the optical beam path. It should be understood that all such variations in optical elements and arrangements may be contemplated by this disclosure.

The optical target 165 may require sufficient exposure time to the mask image to expose the polymer materials to produce the necessary features. The laser output controller 105 may be programmed in any number of ways to provide sufficient exposure time to the laser radiation. In some embodiments, the exposure time may be a fixed period of time. In another embodiment, the exposure time may be based on the material composition of the optical target or its thickness. In another embodiment, exposure time may be based on the size of the primary mask features. In yet another embodiment, the exposure time may be based on the output power of the laser. In still another embodiment, the exposure time may be based at least in part on the intensity of an image obtained by camera 155.

In order to stabilize the optical target 165 during laser exposure, the optical target may be fixed within a frame that is mounted on a movable stage 170. Alternatively, the optical target may be fixed onto the stage without the use of a frame. The stage motion may be controlled in any one or more of an “x”, a “y”, and a “z” direction. One or more actuators may be provided to move the stage. As non-limiting examples, the actuators may comprise any one or more of a linear motor, a piezoelectric actuator, a pneumatic actuator, or a hydraulic actuator. A combination of actuators may move the target horizontally to provide multiple areas that may be sequentially exposed to the first target image, thereby creating a target of repeating features. In addition, the stage may be moved vertically to focus the demagnified image on the target surface. The actuators may be controlled directly by a computer controller 175 through a user interface or via appropriate data and power connections 177. The computer controller 175 may also have a user interface to permit a user to program the motion of the actuators.

In some embodiments, a method of fabricating a laser binary microfabrication mask may include providing a radiation transmittable substrate; contacting the substrate with a water-soluble polymer material, thereby forming an optical target; exposing at least a portion of the optical target to a mask image formed by passing radiation through a primary mask, thereby etching at least a portion of the water-soluble polymer material; contacting the optical target with a metal vapor, thereby forming a metalized target comprising at least one metalized substrate portion and at least one metalized polymer material portion; and exposing the metalized target to an aqueous fluid, thereby removing the metalized polymer material portion. The radiation transmittable substrate may be an ultraviolet radiation transmittable substrate. The radiation can be UV radiation.

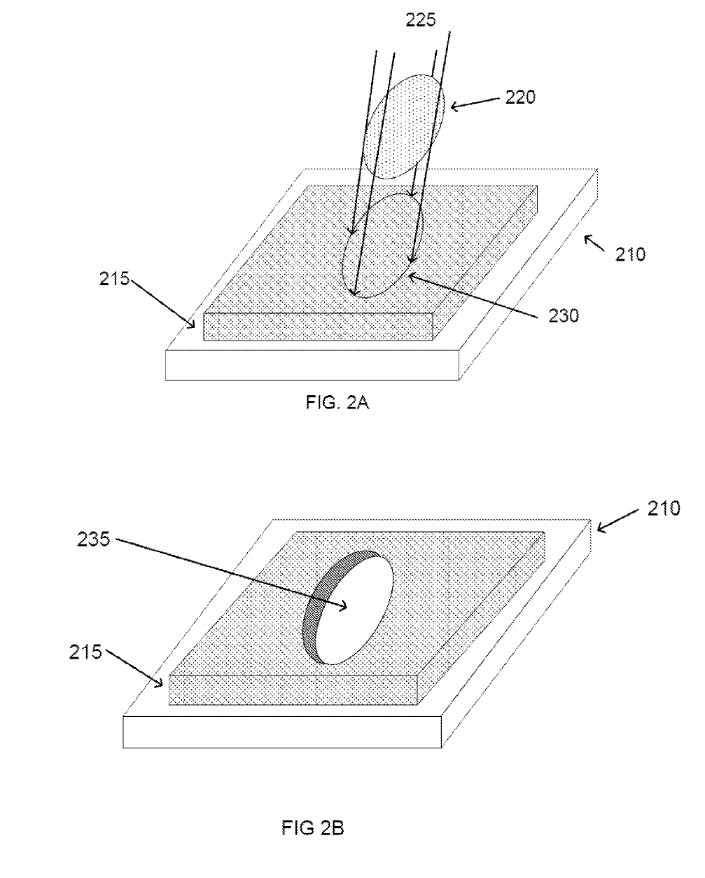

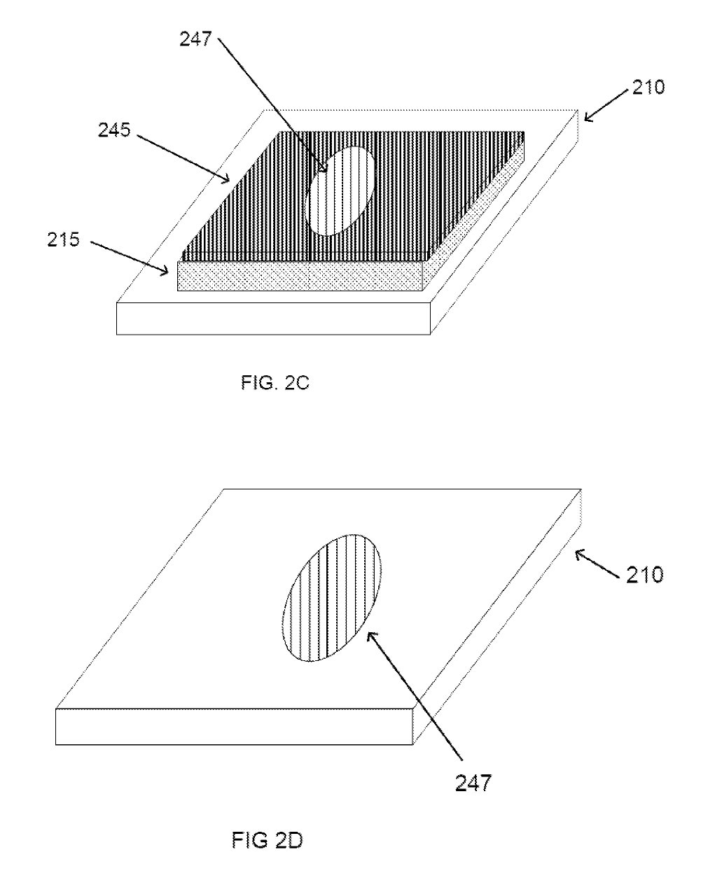

FIGS. 2A-D illustrate one embodiment of a method for processing the optical target during and after radiation exposure. In FIG. 2A, the UV radiation 225 may impinge on a primary mask 220 producing a mask image 230. Although not shown in FIG. 2A, additional optics, such as demagnifying optics, may be placed between the primary mask 220 and the optical target as illustrated in FIG. 1. The optical target may include a UV transmittable substrate material 210 in contact with a water-soluble polymer material 215. The substrate material 210 may comprise any suitable UV transmittable material. In one non-limiting example, the substrate material 210 may transmit radiation having at least one wavelength of about 190 nm to about 360 nm with a transmittance of greater than or about 85%. In another non-limiting example, the substrate material 210 may transmit radiation having at least one wavelength of about 190 nm to about 360 nm with a transmittance of greater than or about 90%. The substrate material 210 may be contacted by a water-soluble polymer material 215 on at least one side of the substrate. Non-limiting examples of such substrate material 210 may include fused silica, calcium fluoride, magnesium fluoride, and fused quartz.

The physical characteristics of the substrate material 210 can provide good optical qualities of the resulting mask at the wavelength for which the substrate may be used. Such physical characteristics may include, as non-limiting examples, surface flatness, wedge angle, and scratch and dig figures. If the mask substrate 210 has a variation of flatness/thickness across the surface, there may be a phase variation at some wavelength of light across the substrate as measured by interferometry. The phase variability may affect the focusing by the substrate 210 in a non-trivial manner. The phase variability may be reported as lambda/“n” in which lambda is the wavelength of the light used to examine the substrate surface 210, and “n” is an even integer related to the number of interference fringes observed in the flatness measurement. In some non-limiting examples, a measurement of lambda/6 as measured using the UV wavelength at which the mask may be used may be a useful amount of flatness. Alternatively, a substrate 210 having a flatness measurement of lambda/6 as measured at 633 nm may also be useful. Substrate material 210 having a flatness of lambda/n, in which n is greater than about six, may also be useful in this application.

The surface characteristics of the substrate material 210 may also include “scratch and dig” values. Such values may indicate the maximum sizes of scratches or pits (digs) present on the polished substrate. The imperfections may be specified by a designation such as “20-10”, “60-40”, or “80-50”, in which the first number indicates the maximum width allowance for a scratch measured in microns, and the second number is the maximum diameter for a dig in hundredths of a millimeter. A substrate material 210 having a scratch and dig value of about 60-40 or better (such as a value of 20-10) may be useful for the applications disclosed above. Additional surface imperfection requirements may include a combined length of the largest scratches on each surface not exceeding about a quarter of the diameter of the substrate 210. Further, in one non-limiting example, the maximum number of digs may be about one or fewer for any 20 mm diameter section on a single surface of the substrate 210.

Yet another useful physical characteristic of the substrate material 210 may include a value of a wedge angle, which represents a deviation of the top and bottom surfaces of the substrate from a true parallel orientation. For an application as substantially disclosed above, a substrate 210 having a wedge angle less than or about 10 arc minutes may be useful.

The water-soluble polymer material 215 may be applied to the substrate material 210 according to any appropriate method including, but not limited to, spin coating, dip coating, evaporative deposition, and cladding. The water-soluble polymer material 215 may comprise any suitable water-soluble material include one or more of polyvinyl pyrrolidone and polyvinyl alcohol. Such water-soluble polymer materials 215 may comprise polymers having a molecular weight of about 10,000 daltons to about 150,000 daltons. Non-limiting examples of such water-soluble polymer materials 215 may have a molecular weight of about 10,000 daltons, about 20,000 daltons, about 40,000 daltons, about 50,000 daltons, about 100,000 daltons, about 125,000 daltons, about 150,000 daltons, or ranges between any two of these values. In one embodiment, the water-soluble polymer material 215 may have a thickness of about 200 nm to about 500 nm. Non-limiting examples of such water-soluble polymer materials 215 may have a thickness of about 200 nm, about 250 nm, about 300 nm, about 350 nm, about 400 nm, about 450 nm, about 500 nm, or ranges between any two of these values. In another embodiment, the water-soluble polymer material 215 may have a thickness of about 20 nm to about 10 μm.

During the fabrication process, the optical target may be exposed to a mask image 230 formed by the laser output radiation 225 impinging on the primary mask 220. At least a portion of the polymer material 215 component of the optical target may be exposed to the mask image 230. The result of the exposure to the incident image may be to remove the polymer material 215, for example by ablation.

FIG. 2B illustrates an example of the results the polymer material being ablated by exposure to the UV radiation. The result of the removal of the polymer material (through ablation is a feature 235 in the polymer material 215 that is the complement of the mask image (230 in FIG. 2A). After the exposed polymer material 215 has been removed from the optical target (for example, by ablation), the optical target may then be composed of the exposed substrate 210 along with polymer material 215 incorporating the mask image feature 235.

The optical target may then be metallized, as illustrated in FIG. 2C. Non-limiting examples of metal that may be deposited on the optical target may include one or more of aluminum, chromium, a nickel/iron alloy, and a nickel/chromium super-alloy. The metal film 245 deposited on the optical target may have a thickness of about 150 nm to about 200 nm. Non-limiting examples of metal film thickness may include about 150 nm, about 160 nm, about 170 nm, about 180 nm, about 190 nm, about 200 nm, or ranges between any two of these values. The optical target may be metalized by means of a coating system including, but not limited to, thermal vapor deposition, E-beam evaporation, coat sputtering, pulsed laser deposition, chemical vapor deposition, or other similar methods. It may be appreciated that the metallization step will result in a metal film 245 coating both the remaining polymer material 215, as well as any exposed substrate material 247.

After the optical target has been metallized, the remaining polymer material 215, which may also be coated with a thin film 245 of metal, may be removed by exposing the optical target to an aqueous fluid. The aqueous fluid may solubilize the remaining polymer material 215 so it may readily be removed from the substrate material 210. In one non-limiting example, the aqueous fluid may comprise distilled water. In other non-limiting example, the aqueous fluid may include one or more of a salt solution, an acidic solution, and a basic solution. Exposing the metalized target to an aqueous solution may include any appropriate means including, but not limited to, one or more of immersion and shaking the metalized target in the aqueous solution. Either or both of these steps may be accomplished for some period of time and/or at some controlled temperature. If both immersion and shaking occur, then the two steps may be run simultaneously or sequentially in any order. The two steps may be run under the same conditions (both time and temperature) or at different times or at different temperatures. In some non-limiting embodiments, the metalized target may be exposed to the aqueous fluid at a temperature of around 300° K. to about 340° K. Non-limiting examples of aqueous fluid temperatures may include about 300° K., about 310° K., about 320° K., about 330° K., about 340° K., or ranges between any two of these values. In one non-limiting example, the aqueous fluid may be at a temperature of around 300° K. In another non-limiting example, the metalized target may be exposed to the aqueous fluid for about 1 minute to about 2 minutes. FIG. 2D illustrates an example of a non-limiting result of exposing the metalized optical target to the aqueous fluid. It may be observed that the binary mask formed at the end of the process may include the UV transparent substrate material 210 with the film representing the mask image feature 247 in contact with the substrate. It may be noted that the mask image feature 247 may be isolated from any other structure on the substrate material 210. It may additionally be appreciated that a final binary mask may comprise one or more features physically isolated from each other.

Additional process steps may also be included in the method to produce a binary mask. In one non-limiting embodiment, the binary mask (which may be considered the optical target after the metalized polymer material has been removed by application of the aqueous fluid) may then be dried. In one non-limiting example, drying the binary mask may be accomplished by gently blowing a gas, such as dry nitrogen gas, over the binary mask. Other gases may be used in the step as well, including one or more of dry argon, dry helium, and dry carbon dioxide. The dry gas may be at any suitable temperature, such as at a temperature of around 300° K. to about 340° K. Non-limiting examples of dry gas temperatures may include about 300° K., about 310° K., about 320° K., about 330° K., about 340° K., or ranges between any two of these values. In one non-limiting example, the dry gas may be at a temperature of around 300° K. An additional step may include examining the binary mask for one or more flaws. Flaws may include one or more of metal film flakes, cracks in the metal film, and retained polymer. In one non-limiting example, the binary mask may be inspected through the use of light microscopy.

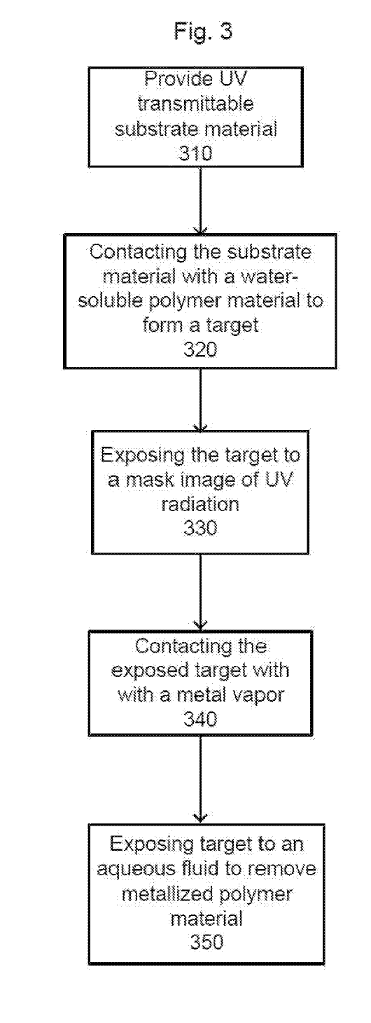

FIG. 3 is a flow chart of an embodiment of a method for manufacturing the binary mask as disclosed above FIG. 2. The method may include providing a substrate material 310 composed of a UV transmittable material as disclosed above. The substrate may be contacted with a water-soluble polymer material 320 including a polymeric material such as polyvinyl alcohol as disclosed above. The polymer material may be applied according the any number of methods including spin coating. For the spin coating method, the amount of polymer material applied to the substrate, as well as the spin rotation rate and time of substrate rotation, may depend on a number of parameters including the viscosity of the polymer material, the polymer material temperature, the desired final thickness of the polymer coating on the substrate, and the molecular weight of the polymer. The polymer material-coated substrate may be considered as an optical target available for exposure to UV radiation. The optical target may then be exposed to a mask image 330 provided by illuminating a primary mask with a source of UV radiation. A variety of optical elements may be used to provide a mask image having the desired size and luminous intensity. Exposure of the polymer material to the mask image may result in polymer material being ablated from the optical target as a result of impinging UV radiation.

After UV exposure resulting in polymer material removal (for example, by ablation), the resulting optical target may be composed of exposed substrate material and substrate material coated with the polymer. The optical target may then be contacted with a metal vapor 340 that may result in the optical target comprising portions that contain metalized substrate material and metalized polymer material. The optical target may then be exposed to an aqueous fluid 350 able to remove the metalized polymer material (or any additional polymer material) from the substrate. The resulting optical target, composed of either exposed or film-coated substrate material may form the binary mask.

It may be appreciated that the resulting binary mask may be used to create micromachined devices such as electronic components or MEMS components. Alternatively, such a binary mask may be used in an iterative process to create additional primary masks having reduced feature size.

### EXAMPLES

### Example 1

### Method for Fabricating Binary Masks

An optical target was fabricated from a fused silica substrate that may transmit UV radiation of about 175 nm to about 360 nm, inclusive of endpoints. A layer of a water-soluble poly vinyl pyrrolidone polymer material was spin-coated on the substrate to a thickness of about 200 nm to about 500 nm. A KrF excimer laser capable of producing 750 mJ pulses with a 25 us pulse width at 248 nm was used to provide the laser output radiation. A homogenizer comprising a pair of 8×8 fixed array insect eye lenses was included to create a uniform illumination field of 20 mm×20 mm at the upstream side of a primary mask. The primary mask was fabricated to have a grid of 100 μm holes. Demagnification optics were selected to provide a mask image having a demagnification ratio of about 10. The target was placed on a micro-machining 3-axis translator to position the target with respect to the demagnified mask image. The optical target was exposed to the mask image from the primary mask in a manner so that the polymer material exposed to the UV radiation was ablated from the optical target. An aluminum film having a thickness of about 150 nm to about 200 nm was deposited on the optical target using physical vapor deposition, thereby depositing the aluminum film of the exposed silica substrate as well as on the polymer material. The aluminum coated polymer material was then removed from the optical target using distilled water. The resulting binary mask had a grid of aluminized pillars or disks about 10 μm in diameter.

Compared to other positive mask photolithography processes, the process disclosed above may take fewer steps, in that only one exposure, one metallization, and one cleaning step may be required. Additionally, other lithographic methods, such as e-beam or X-ray methods, may use polymers like poly methyl-methacrylate or other polymers that may require additional organic etchant solvents like acetone, chlorobenzenes, chloroform, or ketones in the fabrication process. Such organic etchants may require special handling and storage as presenting potentially harmful contaminants to the environment. Further, other than X-ray and some photolithograpy processes, target features greater than about a micron in height may not be easily fabricated. The green process disclosed above may readily be used to fabricate such features.

### Example 2

### Method of Contacting a Substrate with a Water-Soluble Polymer Material

Poly vinyl pyrrolidone (PVP) having an average molecular weight of about 40.000 daltons was dissolved in distilled water to make a solution having a concentration of about 100 mg/ml. The PVP solution was spin coated on a fused silica substrate at about 2000 RPM for about 40 sec. The resulting optical target was then baked at about 75° C. for about 50 sec resulting in a generally uniformly coated substrate.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated in this disclosure, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, or compositions, which can, of course, vary. It is also to be understood that the terminology used in this disclosure is for the purpose of describing particular embodiments only, and is not intended to be limiting.

With respect to the use of substantially any plural and/or singular terms in this disclosure, those having skill in the art can translate from the plural to the singular and/or from the singular to the plural as is appropriate to the context and/or application. The various singular/plural permutations may be expressly set forth in this disclosure for sake of clarity.

It will be understood by those within the art that, in general, terms used in this disclosure, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to.” etc.). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (for example, “a system having at least one of A. B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed in this disclosure also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed in this disclosure can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member.

From the foregoing, it will be appreciated that various embodiments of the present disclosure have been described for purposes of illustration, and that various modifications may be made without departing from the scope and spirit of the present disclosure. Accordingly, the various embodiments disclosed are not intended to be limiting, with the true scope and spirit being indicated by the following claims.

1. A method of fabricating a laser binary microfabrication mask, the method comprising:
providing a radiation transmittable substrate;
contacting the substrate with a water-soluble polymer material, thereby forming an optical target;
exposing at least a portion of the optical target to a mask image formed by passing radiation through a primary mask, thereby etching at least a portion of the water-soluble polymer material;
contacting the optical target with a metal vapor, thereby forming a metalized target comprising at least one metalized substrate portion and at least one metalized polymer material portion; and
exposing the metalized target to an aqueous fluid, thereby removing the metalized polymer material portion.

2. The method of claim 1, wherein providing a radiation transmittable substrate comprises providing an ultraviolet radiation transmittable substrate.

3. The method of claim 1, wherein providing a radiation transmittable substrate comprises providing one or more of the following: fused silica, calcium fluoride, magnesium fluoride, and fused quartz.

4. The method of claim 1, wherein providing a radiation transmittable substrate comprises providing the radiation transmittable substrate that transmits greater than or about 85% of radiation having at least one wavelength of about 360 nm to about 190 nm.

5. (canceled)

6. The method of claim 1, wherein contacting the substrate with a water-soluble polymer material comprises one or more of the following: spin coating, dip-coating, evaporative deposition, and cladding.

7. The method of claim 1, wherein contacting the substrate with a water-soluble polymer material comprises contacting with one or more of polyvinyl pyrrolidone and polyvinyl alcohol.

8. The method of claim 1, wherein contacting the substrate with a water-soluble polymer material comprises contacting with the water-soluble polymer material having a molecular weight of about 10,000 daltons to about 150,000 daltons.

9. (canceled)

10. The method of claim 1, wherein exposing at least a portion of the optical target to a mask image comprises:
providing a laser radiation output;
providing a primary microfabrication mask having a first side and a second side;
focusing the laser radiation output on the first side of the primary microfabrication mask, thereby producing an initial mask image emitted from the second side of the primary microfabrication mask;
providing a demagnification optics system having a focal length to receive the initial mask image, wherein the demagnification optics system is configured to emit a mask image; and
exposing at least a portion of the optical target to the mask image.

11. (canceled)

12. The method of claim 10, wherein providing a laser radiation output comprises providing the laser radiation output having at least one wavelength of about 360 nm to about 190 nm.

13. (canceled)

14. The method of claim 10, wherein providing a laser radiation output comprises providing the laser comprising at least one of an ArF excimer laser, a KrF excimer laser, a XeBr excimer laser, a XeCl excimer laser, a XeF excimer laser, a KrCl excimer laser, a F2 excimer laser, a Nd:YAG laser, an N2 gas laser, and an HeCd laser.

15. The method of claim 10, wherein providing a laser radiation output comprises providing an output from the laser optically coupled through at least one of an attenuator and a homogenizer.

16. The method of claim 10, wherein focusing the laser radiation output comprises focusing the laser radiation output using at least one of a cylindrical lens, a spherical lens, a doublet lens, a triplet lens, a synthetic fused silica lens, and a lens with an anti-reflective coating.

17. The method of claim 10, wherein focusing the laser radiation output comprises focusing the laser radiation output using two cylindrical lenses and one spherical lens.

18. The method of claim 10, wherein providing a laser radiation output comprises providing a laser radiation output that is pulsed, continuous, or both pulsed and continuous.

19. The method of claim 10, wherein providing a laser radiation output comprises providing a pulsed laser radiation output having a pulse width of about 1 ps to about 100 ns.

20. The method of claim 10, wherein providing a demagnification optics system comprises providing a demagnification optics system comprising at least one of a spherical lens corrected for spherical aberration, coma, and astigmatism, a Fresnel lens, a diffractive optics system, a spherical lens, a doublet lens, a triplet lens, a synthetic fused silica lens, and a lens with an anti-reflective coating.

21. The method of claim 10, wherein providing a demagnification optics system comprises providing a demagnification optics system comprising at least one aberration corrected lens having an antireflection coating.

22. The method of claim 10, wherein providing a demagnification optics system comprises providing a demagnification optics system having a demagnification ratio of about 2 to about 25.

23. (canceled)

24. (canceled)

25. The method of claim 1, wherein exposing the metalized target comprises exposing one or more of the following: aluminum, chromium, a nickel/iron alloy, and a nickel-chromium superalloy.

26. The method of claim 1, wherein exposing the metalized target comprises exposing a metal film having a thickness of about 150 nm to about 200 nm.

27. The method of claim 1, wherein contacting the optical target with a metal vapor is carried out by thermal vapor deposition, E-beam evaporation, pulsed laser deposition, or sputtering.

28. The method of claim 1, wherein exposing the metalized target comprises exposing the metalized target to distilled water.

29. The method of claim 1, wherein exposing the metalized target comprises exposing the metalized target to one or more of a salt solution, an acidic solution, and a basic solution.

30. The method of claim 1, wherein exposing the metalized target comprises one or more of immersing and shaking the metalized target in an aqueous fluid at a first temperature of about 300° K. and for a first period of about 1 minute to about 2 minutes.

31. (canceled)

32. (canceled)

33. The method of claim 1, further comprising drying the metalized target exposed to the aqueous fluid.

34. (canceled)

35. The method of claim 1, further comprising examining the metalized target exposed to the aqueous fluid to assess the metalized target for one or more flaws.

36. (canceled)

37. (canceled)

38. The method of claim 1, wherein exposing the metalized target comprises exposing the metalized target with at least one isolated feature.

39. A system for fabricating a laser binary microfabrication mask, the system comprising:
a laser radiation source;
a metal vapor source;
a primary mask having a first side and a second side, the primary mask configured to receive radiation from the laser radiation source on the first side and to emit the radiation on the second side to form a mask image; and
an optical target holder configured to hold an optical target, the optical target comprising a radiation transmittable substrate and a water-soluble polymer material, wherein the optical target holder is configured to perform one or more of the following:
expose at least a portion of the optical target to the mask image to etch at least a portion of the water-soluble polymer material;
contact the optical target with metal vapor from the metal vapor source to form a metalized target comprising at least one metalized substrate portion and at least one metalized polymer material portion; and
expose the metalized target to an aqueous fluid to remove the metalized polymer material portion.

40. The system of claim 39, wherein the radiation transmittable substrate is a UV radiation transmittable substrate and the laser radiation source is a UV radiation source.

41. (canceled)

42. The system of claim 39, wherein the radiation transmittable substrate comprises one or more of the following: fused silica, calcium fluoride, magnesium fluoride, and fused quartz.

43. (canceled)

44. The system of claim 39, wherein the water-soluble polymer material comprises one or more of polyvinyl pyrrolidone and polyvinyl alcohol.

45. The system of claim 39, wherein the water-soluble polymer material has a molecular weight of about 10,000 daltons to about 150,000 daltons.

46. The system of claim 39, further comprising:
a demagnification optics system having a focal length to receive the mask image and to emit a demagnified mask image, wherein the optical target holder is further configured to expose at least a portion of the optical target to the demagnified mask image.

47. (canceled)

48. (canceled)

49. (canceled)

50. The system of claim 39, further comprising at least one of an attenuator and a homogenizer, each configured to be optically coupled to radiation from the laser radiation source.

51. The system of claim 39, further comprising at least one of a cylindrical lens, a spherical lens, a doublet lens, a triplet lens, a synthetic fused silica lens, and a lens with an anti-reflective coating, for focusing radiation from the laser radiation source on the first side of the primary mask.

52. (canceled)

53. (canceled)

54. (canceled)
